(19) United States
(12) Patent Application Publication
(10) Pub. No.: US 2026/0098895 A1
(43) Pub. Date: Apr. 9, 2026

(54) EXPLICIT METHOD FOR PARAMETER SWEEP REDUCTION

(71) Applicant: Tektronix, Inc., Beaverton, OR (US)

(72) Inventor: Kan Tan, Portland, OR (US)

(21) Appl. No.: 19/347,449

(22) Filed: Oct. 1, 2025

Related U.S. Application Data
(60) Provisional application No. 63/705,011, filed on Oct. 8, 2024.

(51) Int. Cl. G01R 31/28; G06F 17/16

(52) U.S. Cl. CPC G01R 31/2837; G06F 17/16

(57) ABSTRACT

A test and measurement system includes a test and measurement instrument, a computing device connected to the test and measurement instrument, and one or more processors configured to execute code that causes the one or more processors to collect measurement data from a full parameter sweep of a first device under test, the full parameter sweep comprising a total number of measurement points for every parameter combination of a number of parameters, identify core parameter sweeps from the full parameter sweep, the core parameter sweeps comprising a total number of measurement points for fewer parameter sweeps than the full parameter sweep, use the core parameter sweeps to calculate auxiliary parameters sweeps. use the core parameter sweeps and the auxiliary parameter sweeps to determine a reduced parameter sweep, and use the reduced parameter sweep for testing subsequent devices under test of a same type as the first device under test.

### CROSS-REFERENCE TO RELATED APPLICATIONS

This disclosure is a non-provisional of and claims benefit from U.S. Provisional Application No. 63/705,011, titled “EXPLICIT METHOD FOR PARAMETER SWEEP REDUCTION,” filed on Oct. 8, 2024, the disclosure of which is incorporated herein by reference in its entirety.

### TECHNICAL FIELD

This disclosure relates to test and measurement, and more particularly to techniques for reducing parameter sweeps for a device.

### BACKGROUND

Sweeping the device parameter space is a critical practice in design, characterization, and manufacturing processes, serving to verify design integrity, deepen understanding of device characteristics, and ensure calibration aligns with design specifications. This comprehensive approach allows engineers to identify and rectify potential flaws, optimize device performance for specific conditions, and adjust for manufacturing or environmental variations, ultimately ensuring the product meets its intended specifications and operates reliably in its intended environment. The parameter sweeps could be for nonlinear calibration, bandwidth extension (BWE) characterization, or instrument noise characterization at different instrument channel settings, for example. These techniques apply to the manufacture of test and measurement instruments themselves, as well as to devices under test (DUTs) connected to instruments for testing and calibration.

The complexity and duration of parameter sweeps escalate quickly with more parameters and finer spacing. For instance, sweeping two parameters at 10 points each requires 10×10=100 combinations, but expanding to sweeping three parameters at 20 points each causes the number of combinations to jump to 20×20×20=8,000 combinations. This exponential growth highlights the challenge in exploring comprehensive parameter spaces, where small increases in parameters or granularity drastically inflate the effort needed.

Given that longer time equates to higher cost, the designers employ various strategies to minimize the number of sweeps. For instance, they might use domain knowledge to select a specific set of sweeps, or leverage machine learning and AI to choose the sweeps based on a large training dataset.

### BRIEF DESCRIPTION OF THE DRAWINGS

FIG. 1 shows an embodiment of a test setup with a test and measurement instrument and a device under test.

FIG. 2 shows an overlay plot of a complete parameter sweep comprised of all measurement points for all parameter sweeps.

FIG. 3 shows a view of a complete parameter sweep configuration.

FIG. 4 shows a plot in logarithmic scale of singular values from a singular value decomposition (SVD) of a complete parameter sweep.

FIG. 5 shows a plot of normalized accumulated sums of singular values from SVD of a complete parameter sweep.

FIG. 6 shows selected core parameter sweeps from the complete parameter sweep.

FIG. 7 shows the parameter sweep having the least error.

FIG. 8 shows the parameter sweep having the largest error.

FIG. 9 shows a parameter sweep with improved accuracy.

### DESCRIPTION

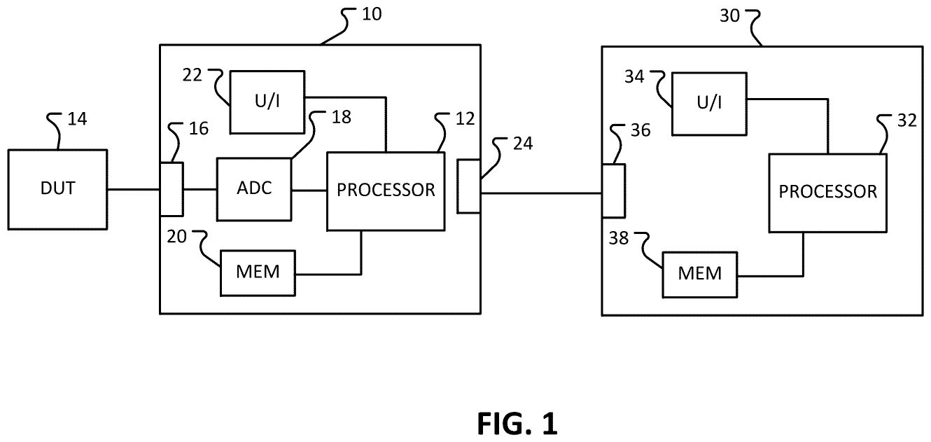

The embodiments disclosed herein describe a test and measurement system and method to perform parameter sweeps for devices under test (DUTs). FIG. 1 shows a diagram of an embodiment of a test and measurement system. The system includes a test and measurement instrument 10, and a computing device 30. The system may also include a device under test (DUT) 14 separate from instrument 10. In one embodiment, the test and measurement instrument may be the DUT. In another embodiment, the test and measurement instrument and the computing device may be the same device. The test and measurement instrument may comprise an oscilloscope, a multimeter, a waveform analyzer, or other test equipment.

The test and measurement instrument generally includes one or more processors such as 12, a user interface 22, one or more ports such as 16 to communicate with the DUT 14 for those embodiments, and one or more ports such as 24 to communicate with the computing device. The test and measurement instrument may include one or more analog to digital converters (ADCs) 18 that convert signals for the DUT into digital data, and one more or memories 20 to store the data. The one or more processors are configured to execute code that causes the one or more processors to perform various tasks in accordance with the embodiments disclosed herein. The computing device 30 also includes one or more ports such as 36 to communicate with the test and measurement instrument, which while shown as a direct, wired connection may comprise a network connection, a wireless connection, etc. Computing device 30 also includes one or more processors 32, a user interface 34 and a memory 38. The one or more processors in the test and measurement instrument that perform the tasks by executing code may reside on the test and measurement instrument, the computing device, or distributed between them. In some embodiments, the test and measurement instrument collects the measurements for a complete parameter sweep, and the computing device performs the parameter sweep reduction, and then the test and measurement instrument uses the reduced parameters for subsequent devices under test.

The embodiments reduce the number of parameter sweeps needed, reducing the amount of time to test DUTs, while maintaining testing standards. The method of the embodiments chooses core parameter sweeps, a subset of the full parameter sweep, after analyzing the full parameter sweep data. The core sweeps contain the majority of information from the complete parameter sweeps. The method then identifies a reduced set of measurement points for the non-core, referred to here as auxiliary parameter sweeps, the subset of the full parameter sweeps that are not included in the core parameter sweeps. The complete set of measurement points in the auxiliary parameter sweep can be predicted from the complete set of measurement points of the core sweeps and the reduced set of measurement points of the auxiliary sweeps.

As used herein, the term “complete parameter sweep” means a set of data that includes every measurement point for every parameter combination, also referred to as parameter sweep, used in the test of a particular device or design. For example, if 10 measurement points are taken for each of 12 parameter sweep, a complete parameter sweep comprises 120 measurement points, and this is a far reduced number of measurement points than actually occurs. Each measurement point for each parameter sweep represents a process of putting the setting on the DUT for that point, then taking a measurement of all measurement points for a given parameter sweep. Then the parameter sweep to be measured is changed and the process is repeated. The engineer must repeat this for every DUT.

The method of the embodiments uses Singular Value Decomposition (SVD) for parameter sweep reduction (PSR) to identify how many parameter sweeps can be reduced. The method, referred to here as the explicit method, identifies the minimum, essential, parameter sweeps, referred to here as the “core” parameter sweeps. The method then approximates the remaining parameter sweeps, referred to here as auxiliary parameter sweeps, by the linear combination of the core parameter sweeps. The linear combination coefficients are determined by a reduced set of measurement points.

The explicit method for PSR has two objectives. The first objective is to determine which parameter sweeps, whether for design, characterization, or calibration, are the core sweeps that encapsulate the majority of the information from the complete set of parameter sweeps. The second objective is to find the solution to approximate the non-core, referred to herein as auxiliary, parameter sweeps as a linear combination of the core parameter sweeps. The linear combination coefficients are determined by a reduced set of measurement points. Since the linear combination incorporates all the core parameter sweeps, this method achieves higher accuracy compared to the traditional approach, which derives each of the non-core parameter sweeps based on just one or two other parameter sweeps.

The parameter sweep data is organized in a matrix X, each column represents the measurement points for one parameter sweep, and each row represents one measurement point for all parameter sweeps. The SVD of matrix X is described in Equation (1).

$$X = U \sum {V}^{T} \qquad ( 1 )$$

where X has a dimension of n×m, the left singular vectors U is a unitary matrix with a dimension of n×n, the singular value matrix Σ has the singular values in the diagonal with a dimension of n×m, the right singular vectors V is a unitary matrix with a dimension of m×m. Typically, n is greater than m. n represents the number of measurement points collected at each parameter sweep. The data, or the measurement points are organized into one single column. m represents the number of the parameter sweeps.

$$\sum = ( \begin{matrix}{σ}_{1} & 0 & ⋯ & 0 \\ 0 & {σ}_{2} & ⋯ & 0 \\ ⋮ & ⋮ & ⋱ & ⋮ \\ 0 & 0 & ⋯ & {σ}_{m} \\ 0 & 0 & ⋯ & 0 \\ ⋮ & ⋮ & ⋱ & ⋮ \\ 0 & 0 & ⋮ & 0\end{matrix} ) \qquad ( 2 )$$

The process then calculates the accumulated sum of the singular values and then normalizes them relative to the total sum so the last accumulated sum equals 1. One must choose a threshold for information coverage. For example, one may select 0.98 as the threshold, signifying that 98% of the information is covered. Then, the process identifies the first accumulated sum that exceeds this threshold. If the first p singular values achieve a sum beyond the threshold, then p parameter sweeps are chosen as the core parameter sweeps.

Once the number of parameter sweeps is determined, the process continues on to identify the core parameter sweeps that will make up that number. Since V is a unitary matrix, multiply both sides of Equation (1) with V yields:

$$XV = U \sum \qquad ( 3 )$$

Note that the singular values from p+1 to m are much smaller than the singular values from 1 to p, they contain minimum information about the parameter sweeps. As an approximation, the singular values from p+1 to m in the matrix 2 are set to 0 in Equation (3). Now the columns of p+1 to m of matrix E are zero column vectors. On the right side of Equation (3), the columns p+1 to m of matrix UZ are zero column vectors as any matrix multiply with zero column vectors will result in zero column vectors. As the submatrix that contains p+1 to m columns on the right side of Equation (3) equals to zero, the submatrix that contains p+1 to m columns on the left side of Equation (3) should also equal to zero.

Based on the observation, the following procedure is designed to identify the core parameter sweeps and the auxiliary parameter sweeps. First the process identifies the columns in matrix X that contribute the most to the p+1 to m columns on the left side of Equation (3), which are approximated as zero column vectors. These columns are the auxiliary parameter sweeps.

The process then denotes the sub matrix of V contains the column p+1 to m as V_{AUX},

$${V}_{AUX} = {V}_{; , p + 1 : m} \qquad ( 4 )$$

and initializes a vector I_{AUX} containing elements of 1 to m−p.

The process starts with the last column (right most) of the matrix V_{AUX} as it corresponds to the smallest singular value of matrix X. It iterates from the last column to left columns, which corresponds to the increasingly greater singular values. The iteration order is determined because a smaller singular value is closer to zero.

The process finds the element in the last column of the matrix V_{AUX} with the largest absolute value and records the row index of this element.

The process then switches the row of matrix V_{AUX} that contains the element with the largest absolute value with the bottom row of matrix V_{AUX}, also switches the corresponding columns of matrix X and elements of the vector I_{AUX}. Then it eliminates the element in last row for all columns, except the last column, by subtracting the scaled last column, update the matrix V_{AUX}.

The process then moves to the next column of the updated matrix V_{AUX} from right to left, repeating the process of finding the element in the next column with the largest absolute value. It records the row index of the identified element, then switch rows of matrix V_{AUX} and columns of the matrix X and elements in the vector I_{AUX} in the same way as for the last column. For example, when the second last column is being looked at, the row containing the element of the updated matrix V_{AUX} with the largest absolute value will be switched with the second row from the bottom. The same operation for the last column is performed to eliminate the element in second row from the bottom on the left columns and update matrix V_{AUX}.

This process is repeated until all columns of the updated matrix V_{AUX} have been through this process. The resulting X matrix after this process is denoted as X_{Switched}. The resulting V_{AUX} after this process is denoted as V_{AUXSwitched} in Equation (5). The resulting I_{AUX} after this process is denoted as I_{AUXSwitched}.

$${V}_{AUXSwitched} = ( \frac{\begin{matrix}{v}_{1 , 1} & {v}_{1 , 2} & ⋯ & {v}_{1 , m - p - 1} & {v}_{1 , m - p} \\ {v}_{2 , 1} & {v}_{2 , 2} & ⋯ & {v}_{2 , m - p - 1} & {v}_{2 , m - p} \\ ⋯ & ⋯ & ⋯ & ⋯ & ⋯ \\ {v}_{p , 1} & {v}_{p , 2} & ⋯ & {v}_{p , m - p - 1} & {v}_{p , m - p}\end{matrix}}{\begin{matrix}{v}_{p + 1 , 1} & {v}_{p + 1 , 2} & ⋯ & {v}_{p + 1 , m - p - 1} & {v}_{p + 1 , m - p} \\ 0 & {v}_{p + 2 , 2} & ⋯ & {v}_{p + 2 , m - p - 1} & {v}_{p + 2 , m - p} \\ ⋮ & ⋮ & ⋱ & ⋮ & ⋮ \\ 0 & 0 & ⋯ & {v}_{m - 1 , m - p - 1} & {v}_{m - 1 , m - p} \\ 0 & 0 & ⋯ & 0 & {v}_{m , m - p}\end{matrix}} ) \qquad ( 5 )$$

The first p columns of matrix X_{Switched} are the core parameter sweeps, denoted as X_{Core}. The remaining columns of matrix X_{Switched} are the auxiliary parameter sweeps, denoted as X_{Auxiliary}. The first p elements in I_{AUXSwitched} contain the index of the core parameter sweeps in the full sweep data X. Note that the same process can be repeated through column p to column 1 of V and update X_{Core}. One should note that these processes are implemented in software and the description here is for ease of understanding.

The process moves on to identify the reduced set of measurements points that can be used to create the linear combination coefficients for the auxiliary parameter sweeps.

By analyzing the full parameter sweep data, the core parameter sweeps are identified. For the same type of designs or devices, the core parameter sweeps will be performed for each design or device. Each of these core parameter sweeps encompasses the entire set of measurement points.

$$[ \begin{matrix}\cdot & {x}_{1 , 2} & \cdot & {x}_{1 , 4} & \cdot & \cdot & \cdot & \cdot & \cdot & \cdot \\ \cdot & {x}_{2 , 2} & \cdot & {x}_{2 , 4} & \cdot & \cdot & \cdot & \cdot & \cdot & \cdot \\ \cdot & {x}_{3 , 2} & \cdot & {x}_{3 , 4} & \cdot & \cdot & \cdot & \cdot & \cdot & \cdot \\ \cdot & {x}_{4 , 2} & \cdot & {x}_{4 , 4} & \cdot & \cdot & \cdot & \cdot & \cdot & \cdot \\ {x}_{5 , 1} & {x}_{5 , 2} & {x}_{5 , 3} & {x}_{5 , 4} & {x}_{5 , 5} & {x}_{5 , 6} & {x}_{5 , 7} & {x}_{5 , 8} & {x}_{5 , 9} & {x}_{5 , 10} \\ \cdot & {x}_{6 , 2} & \cdot & {x}_{6 , 4} & \cdot & \cdot & \cdot & \cdot & \cdot & \cdot \\ \cdot & {x}_{7 , 2} & \cdot & {x}_{7 , 4} & \cdot & \cdot & \cdot & \cdot & \cdot & \cdot \\ \cdot & {x}_{8 , 2} & \cdot & {x}_{8 , 4} & \cdot & \cdot & \cdot & \cdot & \cdot & \cdot \\ \cdot & {x}_{9 , 2} & \cdot & {x}_{9 , 4} & \cdot & \cdot & \cdot & \cdot & \cdot & \cdot \\ \cdot & {x}_{10 , 2} & \cdot & {x}_{10 , 4} & \cdot & \cdot & \cdot & \cdot & \cdot & \cdot \\ {x}_{11 , 1} & {x}_{11 , 2} & {x}_{11 , 3} & {x}_{11 , 4} & {x}_{11 , 5} & {x}_{11 , 6} & {x}_{11 , 7} & {x}_{11 , 8} & {x}_{11 , 9} & {x}_{11 , 10} \\ \cdot & {x}_{12 , 2} & \cdot & {x}_{12 , 4} & \cdot & \cdot & \cdot & \cdot & \cdot & \cdot \end{matrix} ] \qquad Matrix 1$$

For example, as shown in the Matrix 1 above, the 2^{nd} and 4^{th} columns are the core parameter sweeps. Each sweep makes the full measurements that cover 12 measurement points.

The process moves on to identify the reduced set of measurement points for the auxiliary parameter sweeps, based on the measurement points encompassed by the core parameter sweeps. In this process, one can make two observations. First, the measurement points of each of the auxiliary parameter sweep can be approximated by the linear combinations of the core parameter sweep measurement points. Second, since there are p core parameter sweeps, a minimum of p measurement points is needed to determine the linear combination coefficients for each auxiliary parameter sweeps.

Since there are n measurement points for each core parameter sweep, choosing the p measurement points that have the best condition value of the p×p submatrix containing the p rows in X_{Core} improves the numerical results. One should note that the number of rows selected is the same number of rows as there are core parameter sweeps. The problem of picking p rows from n rows to have the submatrix with the best condition value can be solved in one of several ways. One could perform an exhaustive search in which the process calculates the condition value for all possible submatrix, then picks the one with the smallest condition value. One could formulate the problem into an optimization problem and solve the optimization problem numerically. One could find the sub-optimal solution using the column permutation (pivoting) QR factorization.

Using column permutation with QR Factorization offers a quick solution that requires minimum processing time. In this method, the process performs the pivoting QR factorization on the transpose of matrix X_{Core} containing the core parameter sweeps. The pivoting QR factorization routine returns the permutation vector, the first p elements in the permutation vector are chosen as the indexes for the p rows. For example, Matrix 1 shows the example with the 5^{th} and the 11^{th} rows being selected as the reduced set of measurement points that can be used to create the linear combination coefficients.

The reduced set of measurement points, shown in Matrix 1, have been identified. The process calculates the approximation of the auxiliary parameter sweeps from the core parameter sweeps and the reduced set of measurement points.

The measurement points of the auxiliary parameter sweeps can be approximated by linear combinations of the measurement points from the core parameter sweeps. The linear combination coefficients for each of the auxiliary parameter sweeps can be obtained with the reduced set of measurement points identified in the previous step: solve c from A, b in Equation (6), where A is a submatrix of X_{Core} composed of the p rows identified in the previous section. b is a vector containing the p measurement points for the auxiliar parameter sweep. c is the vector containing the linear combination coefficients:

$$Ac = b \qquad ( 6 )$$

When more than p measurement points are taken to increase the approximation accuracy, the least mean squared (LMS) solution can be found from Equation (6). In the numerical example described in next section, the case is included for more than p measurement points.

Once the linear combination coefficients are obtained from Equation (6), the complete set of measurement points for the auxiliary parameter sweep can be calculated from Equation (7).

$${x}_{AUX ( : , i )} = {X}_{Core} c \qquad ( 7 )$$

Now the entirety of measurement points for the design or device are obtained as shown in Matrix 2.

$$[ \begin{matrix}{x}_{1 , 1} & {x}_{1 , 2} & {x}_{1 , 3} & {x}_{1 , 4} & {x}_{1 , 5} & {x}_{1 , 6} & {x}_{1 , 7} & {x}_{1 , 8} & {x}_{1 , 9} & {x}_{1 , 10} \\ {x}_{2 , 1} & {x}_{2 , 2} & {x}_{2 , 3} & {x}_{2 , 4} & {x}_{2 , 5} & {x}_{2 , 6} & {x}_{2 , 7} & {x}_{2 , 8} & {x}_{2 , 9} & {x}_{2 , 10} \\ {x}_{3 , 1} & {x}_{3 , 2} & {x}_{3 , 3} & {x}_{3 , 4} & {x}_{3 , 5} & {x}_{3 , 6} & {x}_{3 , 7} & {x}_{3 , 8} & {x}_{3 , 9} & {x}_{3 , 10} \\ {x}_{4 , 1} & {x}_{4 , 2} & {x}_{4 , 3} & {x}_{4 , 4} & {x}_{4 , 5} & {x}_{4 , 6} & {x}_{4 , 7} & {x}_{4 , 8} & {x}_{4 , 9} & {x}_{4 , 10} \\ {x}_{5 , 1} & {x}_{5 , 2} & {x}_{5 , 3} & {x}_{5 , 4} & {x}_{5 , 5} & {x}_{5 , 6} & {x}_{5 , 7} & {x}_{5 , 8} & {x}_{5 , 9} & {x}_{5 , 10} \\ {x}_{6 , 1} & {x}_{6 , 2} & {x}_{6 , 3} & {x}_{6 , 4} & {x}_{6 , 5} & {x}_{6 , 6} & {x}_{6 , 7} & {x}_{6 , 8} & {x}_{6 , 9} & {x}_{6 , 10} \\ {x}_{7 , 1} & {x}_{7 , 2} & {x}_{7 , 3} & {x}_{7 , 4} & {x}_{7 , 5} & {x}_{7 , 6} & {x}_{7 , 7} & {x}_{7 , 8} & {x}_{7 , 9} & {x}_{7 , 10} \\ {x}_{8 , 1} & {x}_{8 , 2} & {x}_{8 , 3} & {x}_{8 , 4} & {x}_{8 , 5} & {x}_{8 , 6} & {x}_{8 , 7} & {x}_{8 , 8} & {x}_{8 , 9} & {x}_{8 , 10} \\ {x}_{9 , 1} & {x}_{9 , 2} & {x}_{9 , 3} & {x}_{9 , 4} & {x}_{9 , 5} & {x}_{9 , 6} & {x}_{9 , 7} & {x}_{9 , 8} & {x}_{9 , 9} & {x}_{9 , 10} \\ {x}_{10 , 1} & {x}_{10 , 2} & {x}_{10 , 3} & {x}_{10 , 4} & {x}_{10 , 5} & {x}_{10 , 6} & {x}_{10 , 7} & {x}_{10 , 8} & {x}_{10 , 9} & {x}_{10 , 10} \\ {x}_{11 , 1} & {x}_{11 , 2} & {x}_{11 , 3} & {x}_{11 , 4} & {x}_{11 , 5} & {x}_{11 , 6} & {x}_{11 , 7} & {x}_{11 , 8} & {x}_{11 , 9} & {x}_{11 , 10} \\ {x}_{12 , 1} & {x}_{12 , 2} & {x}_{12 , 3} & {x}_{12 , 4} & {x}_{12 , 5} & {x}_{12 , 6} & {x}_{12 , 7} & {x}_{12 , 8} & {x}_{12 , 9} & {x}_{12 , 10}\end{matrix} ] \qquad Matrix 2$$

The total number of actual measurement points depicted in Matrix 1 is 2×(12+10)−2×2=40. All the measurement points presented in Matrix 2 amount to 12×10=120. Therefore, the reduction in measurement points from the complete parameter sweep to the reduced set of measurement points is a factor of 3, as demonstrated by the ratio 120/40=3. The reduced set of measurement points is then used on subsequent devices under test of a same design or same type.

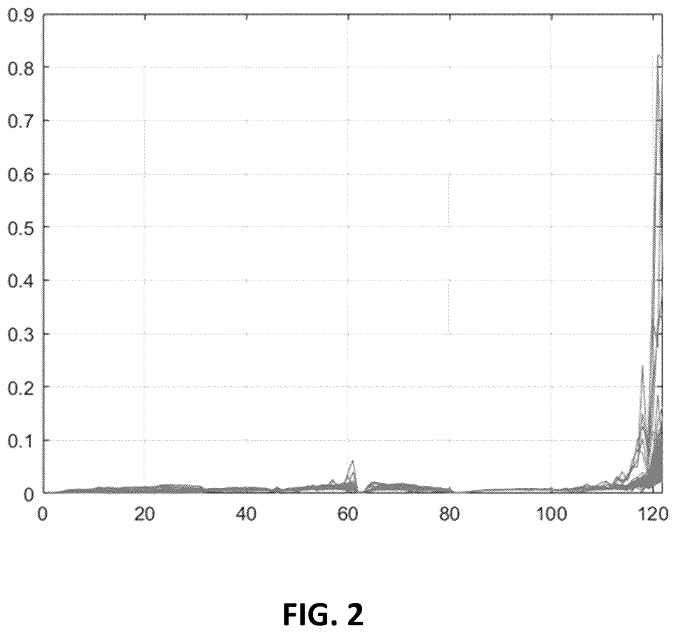

In this numerical example, three parameters are swept. All measurement points for all parameter sweeps are plotted together in FIG. 2.

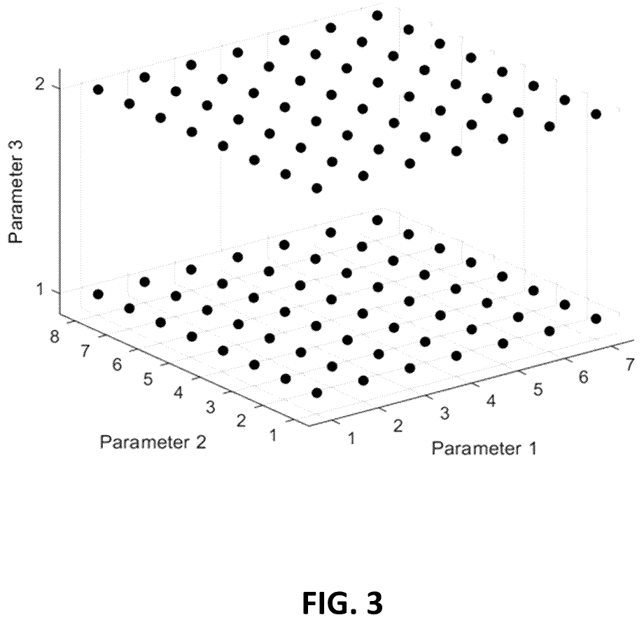

FIG. 3 shows all parameter sweeps, in which each dot represents one sweep for one single parameter combination.

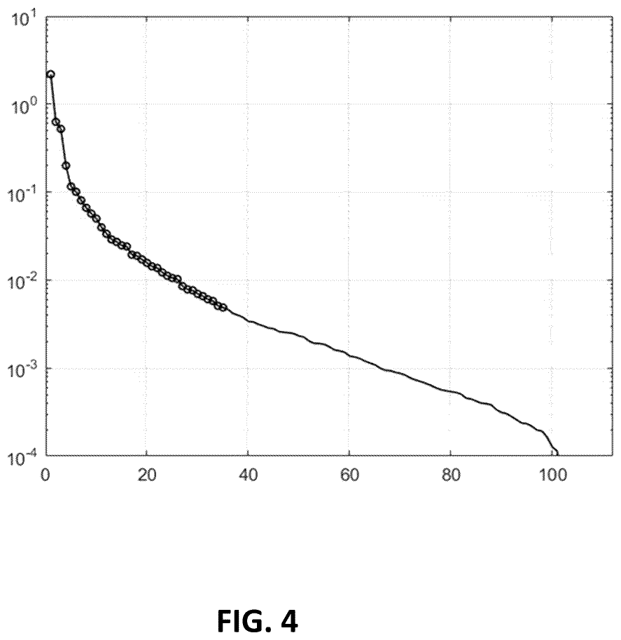

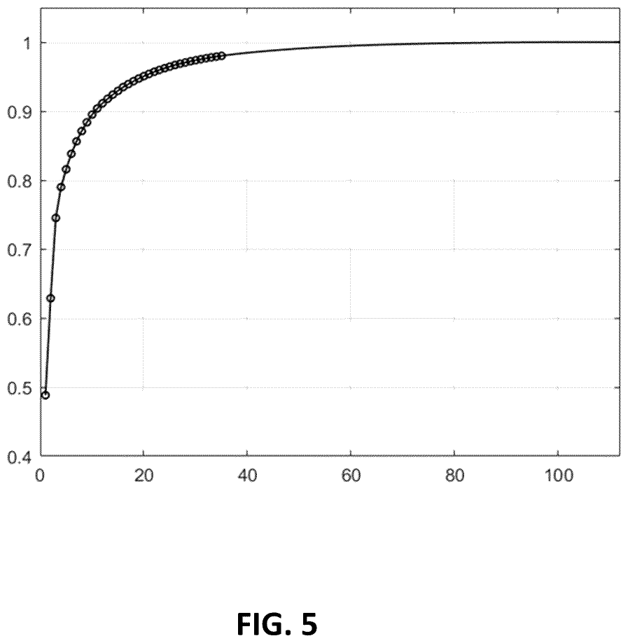

The singular values from the SVD and the normalized accumulated sum are shown in FIG. 4 and FIG. 5. The points that provide more than 98% of the accumulated sum are marked as circles. One should note that this reflects a selection of 98% as the threshold, which could be a different value. These plots are shown for ease of understanding. When this process operates on the computing device, these plots may be created and saved, but the software will make the determinations numerically.

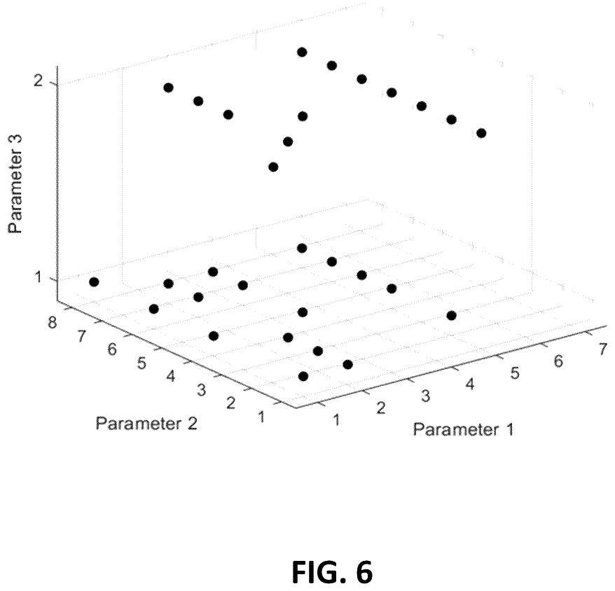

The selected core parameter sweeps are shown as dots in FIG. 6. There are significantly fewer dots in FIG. 6 than those in FIG. 3, indicating the effectiveness of parameter sweep reduction (PSR).

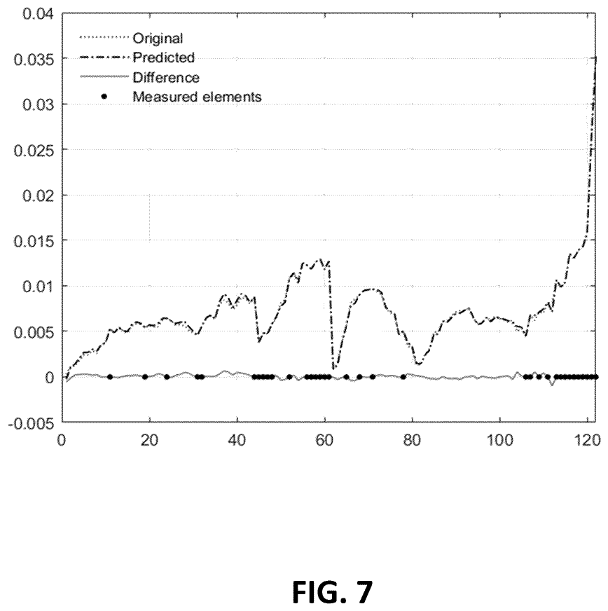

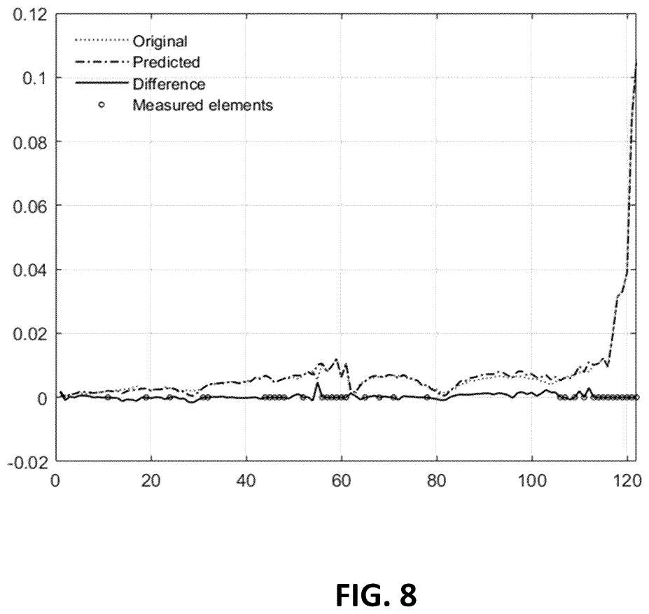

When using the explicit method for PSR, the measurement points for the auxiliary parameter sweeps can be approximated by linear combinations of the measurement points from the core parameter sweeps. Once the approximation for all the auxiliary parameter sweeps is completed, the prediction, or approximation, error defined as the difference between the approximation and the actual measurement points can be calculated for each of all auxiliary parameter sweeps. The process collects the peak magnitude of the error for each parameter sweep. The sweep with the least and largest peak are shown for reference in FIG. 7 and FIG. 8. The circles in the figures indicate which measurement points are taken to calculate the linear combination coefficients in Equation (6).

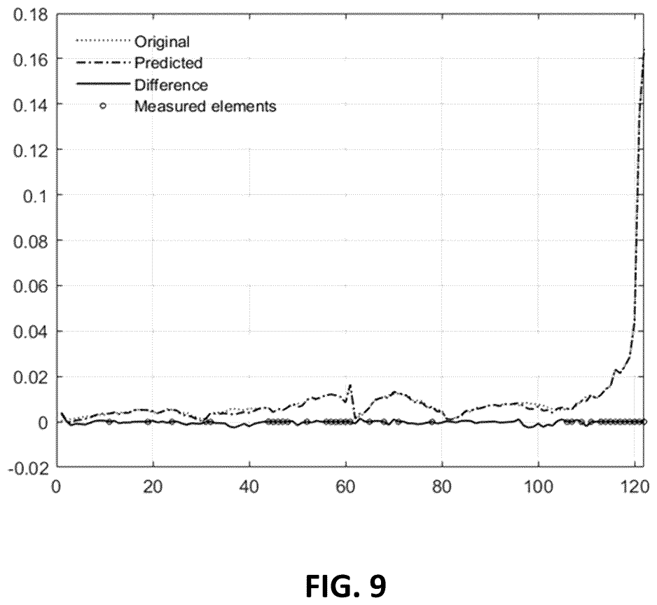

One should note the relatively large approximation errors observed at isolated measurement points. To reduce the errors, the process can include those measurement points to actual measurements for the auxiliary parameter sweeps. The software would identify those measurement points having an error above some threshold and then include the actual measurement points when calculating the auxiliary parameter sweeps. With that, the peak prediction error becomes smaller for the worst auxiliary parameter sweep, as shown in FIG. 9.

The embodiments here involve an explicit method for parameter sweep reduction (PSR). The linear algebra techniques including SVD and pivoting QR factorization are used to identify the core parameter sweeps and the reduced set of measurement points. The explicit method for PSR is computationally efficient and can then be used for subsequent designs or device of the same kind as the one for which the PSR was performed. The reduction in the total number of measurement points to cover all the parameter sweeps is significantly reduced, which translates to faster manufacturing throughput, lower cost, and reduced power consumption. The method has a wide range of applications including design simulation, factory calibration and instrument signal path calibration (SPC), for existing and new devices. For instance, the oscilloscope high-frequency calibration and SPC including nonlinear calibration, BWE (broadband waveguide calibration) characterization, and oscilloscope noise characterization.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

### EXAMPLES

Illustrative examples of the disclosed technologies are provided below. An embodiment of the technologies may include one or more, and any combination of, the examples described below.

Example 1 is a test and measurement system, comprising: a test and measurement instrument; a computing device connected to the test and measurement instrument; and one or more processors configured to execute code that causes the one or more processors to: collect measurement data from a full parameter sweep of a first device under test, the full parameter sweep comprising a total number of measurement points for every parameter combination of a number of parameters; identify core parameter sweeps from the full parameter sweep, the core parameter sweeps comprising a total number of measurement points for fewer parameter sweeps than the full parameter sweep; use the core parameter sweeps to calculate auxiliary parameters sweeps; use the core parameter sweeps and the auxiliary parameter sweeps to determine a reduced parameter sweep; and use the reduced parameter sweep for testing subsequent devices under test of a same type as the first device under test.

Example 2 is the test and measurement system of Example 1, wherein the device under test comprises the test and measurement instrument.

Example 3 is the test and measurement system of either of Examples 1 or 2, wherein the device under test is separate from the test and measurement instrument.

Example 4 is the test and measurement system of any of Examples 1 through 3, wherein the code that causes the one or more processors to identify core parameter sweeps comprises code that causes the one or more processors to perform singular value decomposition on a measurement matrix comprised of n measurements by m parameters.

Example 5 is the test and measurement system of Example 4, wherein the code that causes the one or more processors to perform singular value decomposition comprises code that causes the one or more processors to identify a number of parameter sweeps, p, that contains a majority of information contained in the full parameter sweep.

Example 6 is the test and measurement system of Example 5, wherein the code that causes the one or more processors to identify the p sweeps that exceed a selected threshold comprises code that causes the one or more processors to identify columns in the measurement matrix as the core parameter sweeps.

Example 7 is the test and measurement system of any of Examples 1 through 6, wherein the code that causes the one or more processors to use the core parameter sweeps to calculate the auxiliary parameter sweeps comprises code that causes the one or more processors to use a linear combination of the core parameter sweeps to produce the auxiliary parameter sweeps.

Example 8 is the test and measurement system of Example 7, wherein the code that causes the one or more processors to use the core parameter sweeps to calculate the auxiliary parameter sweeps comprises code that causes the one or more processors to select a number of rows, p, from a measurement matrix of n measurements by m parameters to use in the linear combination.

Example 9 is the test and measurement system of Example 8, wherein the code that causes the one or more processors to select the p rows from the measurement matrix of n measurements by m parameters comprises code to cause the one or more processors to use column permutation with QR factorization to produce indices for rows in the measurement matrix as the p rows.

Example 10 is the test and measurement system of any of Examples 1 through 9, wherein the one or more processors are further configured to determine an error in the auxiliary parameter sweeps and identify any isolated measurement points with an approximation error above a predetermined threshold.

Example 11 is the test and measurement system of Example 10, wherein the one or more processors are further configured to execute code that causes the one or processors to include measurements from any isolated measurement points with the approximation error above the predetermined threshold to determine the measurement points for the auxiliary parameter sweeps.

Example 12 is a method, comprising: collecting measurement data from a full parameter sweep of a first device under test, the full parameter sweep comprising a total number of measurement points for every parameter combination of a number of parameters; identifying core parameter sweeps from the full parameter sweep, the core parameter sweeps comprising a total number of measurement points for fewer parameter sweeps than the full parameter sweep; using the core parameter sweeps to calculate auxiliary parameters sweeps; using the core parameter sweeps and the auxiliary parameter sweeps to determine a reduced parameter sweep; and using the reduced parameter sweep for testing subsequent devices under test of the same type as the first device under test.

Example 13 is the method of Example 12, wherein identifying core parameter sweeps comprises singular value decomposition on a measurement matrix comprised of n measurements by m parameters.

Example 14 is the method of Example 13, wherein performing singular value decomposition comprises identifying a number of parameter sweeps, p, that contains a majority of information contained in the full parameter sweep.

Example 15 is the method of Example 14, wherein identifying the p sweeps comprises identifying columns in the measurement matrix as the core parameter sweeps.

Example 16 is the method of any of Examples 12 through 15, wherein using the core parameter sweeps to calculate the auxiliary parameter sweeps comprises using a linear combination of the core parameter sweeps to produce the auxiliary parameter sweeps.

Example 17 is the method of Example 16, wherein using the core parameter sweeps to calculate the auxiliary parameter sweeps comprises selecting a number of rows, p, from a measurement matrix of n measurements by m parameters to use in the linear combination.

Example 18 is the method of Example 17, wherein selecting p rows comprises using column permutation with QR factorization to produce indices for rows in the measurement matrix as the p rows.

Example 19 is the method of any of Examples 12 through 15, further comprising determining an error in the auxiliary parameter sweeps and identifying any isolated measurement points with an approximation error above a predetermined threshold.

Example 20 is the method of Example 19, further comprising using measurements from any of the isolated measurement points with the approximation error above the predetermined threshold to determine the measurement points for the auxiliary parameter sweeps.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement system, comprising:
a test and measurement instrument;
a computing device connected to the test and measurement instrument; and
one or more processors configured to execute code that causes the one or more processors to:
collect measurement data from a full parameter sweep of a first device under test, the full parameter sweep comprising a total number of measurement points for every parameter combination of a number of parameters;
identify core parameter sweeps from the full parameter sweep, the core parameter sweeps comprising a total number of measurement points for fewer parameter sweeps than the full parameter sweep;
use the core parameter sweeps to calculate auxiliary parameters sweeps;
use the core parameter sweeps and the auxiliary parameter sweeps to determine a reduced parameter sweep; and
use the reduced parameter sweep for testing subsequent devices under test of a same type as the first device under test.

2. The test and measurement system as claimed in claim 1, wherein the device under test comprises the test and measurement instrument.

3. The test and measurement system as claimed in claim 1, wherein the device under test is separate from the test and measurement instrument.

4. The test and measurement system as claimed in claim 1, wherein the code that causes the one or more processors to identify core parameter sweeps comprises code that causes the one or more processors to perform singular value decomposition on a measurement matrix comprised of n measurements by m parameters.

5. The test and measurement system as claimed in claim 4, wherein the code that causes the one or more processors to perform singular value decomposition comprises code that causes the one or more processors to identify a number of parameter sweeps, p, that contains a majority of information contained in the full parameter sweep.

6. The test and measurement system as claimed in claim 5, wherein the code that causes the one or more processors to identify the p sweeps that exceed a selected threshold comprises code that causes the one or more processors to identify columns in the measurement matrix as the core parameter sweeps.

7. The test and measurement system as claimed in claim 1, wherein the code that causes the one or more processors to use the core parameter sweeps to calculate the auxiliary parameter sweeps comprises code that causes the one or more processors to use a linear combination of the core parameter sweeps to produce the auxiliary parameter sweeps.

8. The test and measurement system as claimed in claim 7, wherein the code that causes the one or more processors to use the core parameter sweeps to calculate the auxiliary parameter sweeps comprises code that causes the one or more processors to select a number of rows, p, from a measurement matrix of n measurements by m parameters to use in the linear combination.

9. The test and measurement system as claimed in claim 8, wherein the code that causes the one or more processors to select the p rows from the measurement matrix of n measurements by m parameters comprises code to cause the one or more processors to use column permutation with QR factorization to produce indices for rows in the measurement matrix as the p rows.

10. The test and measurement system as claimed in claim 1, wherein the one or more processors are further configured to determine an error in the auxiliary parameter sweeps and identify any isolated measurement points with an approximation error above a predetermined threshold.

11. The test and measurement system as claimed in claim 10, wherein the one or more processors are further configured to execute code that causes the one or processors to include measurements from any isolated measurement points with the approximation error above the predetermined threshold to determine the measurement points for the auxiliary parameter sweeps.

12. A method, comprising:
collecting measurement data from a full parameter sweep of a first device under test, the full parameter sweep comprising a total number of measurement points for every parameter combination of a number of parameters;
identifying core parameter sweeps from the full parameter sweep, the core parameter sweeps comprising a total number of measurement points for fewer parameter sweeps than the full parameter sweep;
using the core parameter sweeps to calculate auxiliary parameters sweeps;
using the core parameter sweeps and the auxiliary parameter sweeps to determine a reduced parameter sweep; and
using the reduced parameter sweep for testing subsequent devices under test of the same type as the first device under test.

13. The method as claimed in claim 12, wherein identifying core parameter sweeps comprises singular value decomposition on a measurement matrix comprised of n measurements by m parameters.

14. The method as claimed in claim 13, wherein performing singular value decomposition comprises identifying a number of parameter sweeps, p, that contains a majority of information contained in the full parameter sweep.

15. The method as claimed in claim 14, wherein identifying the p sweeps comprises identifying columns in the measurement matrix as the core parameter sweeps.

16. The method as claimed in claim 12, wherein using the core parameter sweeps to calculate the auxiliary parameter sweeps comprises using a linear combination of the core parameter sweeps to produce the auxiliary parameter sweeps.

17. The method as claimed in claim 16, wherein using the core parameter sweeps to calculate the auxiliary parameter sweeps comprises selecting a number of rows, p, from a measurement matrix of n measurements by m parameters to use in the linear combination.

18. The method as claimed in claim 17, wherein selecting p rows comprises using column permutation with QR factorization to produce indices for rows in the measurement matrix as the p rows.

19. The method as claimed in claim 12, further comprising determining an error in the auxiliary parameter sweeps and identifying any isolated measurement points with an approximation error above a predetermined threshold.

20. The method as claimed in claim 19, further comprising using measurements from any of the isolated measurement points with the approximation error above the predetermined threshold to determine the measurement points for the auxiliary parameter sweeps.
